(19) United States
(12) Patent Application Publication
(10) Pub. No.: US 2009/0200648 A1
(43) Pub. Date: Aug. 13, 2009

(54) Embedded die system and method

(75) Inventor: Irvin W. Graves, JR., San Jose, CA (US)

Correspondence Address: APPLE INC.;c/o Fletcher Yoder, PC, P.O. Box 692289, Houston, TX, 77269-2289, US

(73) Assignee: Apple Inc.

(21) Appl. No.: 12/069,376

(22) Filed: Feb. 8, 2008

(51) Int. Cl. H01L 23/552; H01L 21/52; H05K 1/03

(52) U.S. Cl. 257/659; 174/254; 438/121; 257/E21.5; 257/E23.114

(57) ABSTRACT

A method and system is disclosed for facilitating miniaturization of an electronic device by efficiently utilizing available space. Specifically, in an exemplary embodiment, there is provided an electronic device comprising a substrate, a cavity formed in the substrate, and a bridge coupled to the substrate such that it spans the cavity. Further, the device may include a semiconductor device coupled to the bridge such that the semiconductor device is positioned within the cavity. In some embodiments, the bridge may include a tape automated bonding (TAB) tape having various layers, including a layer configured to provide electromagnetic shielding.

### BACKGROUND OF THE INVENTION

1. Field of the Invention

Embodiments of the present invention relate generally to devices and methods that efficiently utilize space and/or improve performance of electronic equipment by including a die integral to a substrate via a cavity or aperture in the substrate.

2. Description of the Related Art

This section is intended to introduce the reader to various aspects of art that may be related to various aspects of the present invention, which are described and/or claimed below. This discussion is believed to be helpful in providing the reader with background information to facilitate a better understanding of the various aspects of the present invention. Accordingly, it should be understood that these statements are to be read in this light, and not as admissions of prior art.

Miniaturization may be described as a continuing trend in technology toward ever-smaller scales for devices. Miniaturization may include reducing the size of a specific device. For example, transistors, capacitors, inductors, resistors, and diodes may be reduced in size, while retaining the same operational characteristics. Miniaturization may also include more efficient utilization of available space. For example, an electronic device may be miniaturized by more effectively arranging components of the device such that the device requires less space to contain all of its various components.

In the field of electronics, it is often desirable to miniaturize equipment to facilitate convenient use of the equipment. For example, in the cell phone industry, smaller phones are desirable because users can more easily transport and store a phone that takes up less space. Additionally, miniaturization may facilitate inclusion of additional features in a single device, which may be advantageous because it eliminates the need for multiple devices. Indeed, miniaturization of a device may include more effectively utilizing available space for a particular component, which makes space available for additional components. For example, if certain components of a digital music player are reduced in size, the space previously occupied by the now miniaturized components may be utilized for an additional feature, such as camera circuitry, cell phone circuitry, a sound recorder, or the like.

Accordingly, it may be desirable to miniaturize electronic devices. More particularly, it may be advantageous to miniaturize electronic devices without sacrificing functionality.

### SUMMARY

Certain aspects of embodiments disclosed herein by way of example are summarized below. It should be understood that these aspects are presented merely to provide the reader with a brief summary of certain forms an invention disclosed and/or claimed herein might take and that these aspects are not intended to limit the scope of any invention disclosed and/or claimed herein. Indeed, any invention disclosed and/or claimed herein may encompass a variety of aspects that may not be set forth below.

Present embodiments relate to devices, systems, and methods for providing electronic equipment with an embedded semiconductor device. In one embodiment, there is provided an electronic device (e.g., a cellular telephone) that efficiently utilizes available space by positioning a semiconductor device (e.g., a processor) within a cavity in a substrate of the device. For example, the substrate may include a printed circuit board or device housing that has a cavity, opening, or hole that has been formed in the substrate via an embossing tool or laser. Additionally, the device may include a bridge coupled to the substrate and spanning the cavity such that the bridge can hold the semiconductor device within the cavity. For example, the bridge may include a piece of tape that couples to the substrate on either side of the cavity. Further, the semiconductor device may be coupled to a side of the bridge that is directly adjacent and above the cavity such that the semiconductor device is positioned within the cavity.

Additionally, present embodiments may provide efficient electromagnetic shielding of the semiconductor device disposed within the cavity. For example, the bridge that is designed to span the cavity may include a tape automated bonding (TAB) tape that is formed from four layers, including an electromagnetic shielding layer. The electromagnetic shielding layer may include a metallic mesh or the like that cooperates with a layer of electromagnetic shielding material disposed within the cavity to shield the semiconductor device when it is positioned between the TAB tape and the walls of the cavity. The other layers of the TAB tape may include a laminated metal layer, a polymer layer, and an adhesive layer. In some embodiments fewer layers may be utilized. Further, it should be noted that present embodiments may include providing such TAB tape with a previously attached semiconductor device that is arranged for placement within a substrate cavity.

### BRIEF DESCRIPTION OF THE DRAWINGS

These and other features, aspects, and advantages of the present invention will become better understood when the following detailed description of certain embodiments is read with reference to the accompanying drawings in which like characters represent like parts throughout the drawings, wherein:

FIG. 1 is a cross-sectional view of a semiconductor device integrated with a substrate of an electronic device in accordance with present embodiments;

FIG. 2 is a cross-sectional view of the embodiment of FIG. 1, wherein a hole extends through the substrate in accordance with present embodiments;

FIG. 3 is a perspective view of a cavity and trenches formed in a substrate of an electronic device and configured to receive a TAB mounted die in accordance with present embodiments;

FIG. 4 is a perspective view of the cavity and trenches formed in the substrate FIG. 3, wherein the cavity and trenches are electroplated with a metallic layer in accordance with present embodiments;

FIG. 5 illustrates a TAB mounted die feature configured for coupling with a cavity and a substrate in accordance with present embodiments;

FIG. 6 is a perspective view of a TAB mounted die feature coupled with a substrate such that an integrated circuit is suspended within a cavity of the substrate in accordance with present embodiments;

FIG. 7 illustrates a TAB mounted die feature configured for coupling with a cavity and a substrate, wherein the TAB mounted die feature includes a tab configured to communicatively couple to a feature of the substrate in accordance with present embodiments;

FIG. 8 is a perspective view of the cavity and substrate illustrated in FIG. 4, wherein the substrate includes a conductive pad extending from the metallic layer in accordance with present embodiments;

FIG. 9 is a cross-sectional view of an exemplary bridge material in accordance with present embodiments;

FIG. 10 is a flow chart of a method in accordance with present embodiments; and

FIG. 11 is a flow chart of a method in accordance with present embodiments.

### DETAILED DESCRIPTION OF SPECIFIC EMBODIMENTS

One or more specific embodiments of the present invention will be described below. These described embodiments are only exemplary of the present invention. Additionally, in an effort to provide a concise description of these exemplary embodiments, all features of an actual implementation may not be described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Embodiments of the present invention are directed to systems and methods related to embedding semiconductor devices directly into a feature or component (e.g., a housing or circuit board) of an electronic device. The semiconductor devices may be mounted to tape via a TAB technique or mounted to a lead frame, and held or suspended within an opening in a substrate of the device via the tape or lead frame. For example, one embodiment may include a die disposed within a cavity or hole formed in a thermoplastic enclosure of a cellular telephone such that the die extends down into the cavity or hole from a piece of tape coupled to at least two sides of the cavity or hole. Another embodiment may include a die positioned within a cavity or hole formed in a printed circuit board such that the die extends into the cavity or hole from one side of a piece of tape that spans the cavity or hole. It should be noted that the cavity or hole may be formed via numerous techniques, such as through the use of a hot embossing tool or a laser. Additional examples and specific features of present embodiments will be discussed in further detail below.

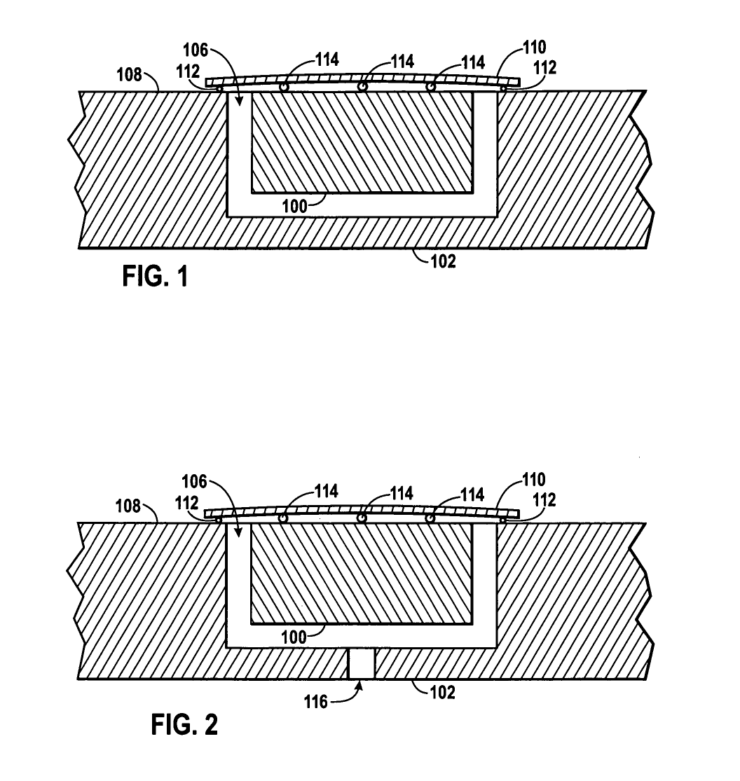

Turning now to the figures, FIG. 1 depicts a cross-sectional view of a semiconductor device 100 (e.g., a processor or a memory) integrated with a substrate 102 of an electronic device (e.g., a hearing aid, a blue tooth headset, a watch, an implantable medical device, a phone, or a portable television) in accordance with present embodiments. The substrate 102 may be a component of a computer, a cell phone, a digital music player, or the like. For example, the substrate 102 may include a printed circuit board or thermoplastic device housing. By integrating the semiconductor device 100 with the substrate 102, space may be conserved within the electronic device (e.g., cell phone). Further, performance of the electronic device may be improved by integrating the semiconductor device 100 with the substrate 102, as will be discussed in further detail below.

As illustrated in FIG. 1, the substrate 102 includes a cavity 106 in accordance with present embodiments. The semiconductor device 100 (e.g., an integrated circuit) may be positioned within the cavity 106 to conserve space on an outer surface 108 of the substrate 102. Specifically, the semiconductor device 100 may be held within the cavity 106 by a connection to a bridge 110 (e.g., a piece of tape or a lead frame). Embodiments employing a lead frame may include a layer (e.g., tape) positioned above the lead frame to provide protection or shielding.

The bridge 110 spans the cavity 106 and may communicatively couple to the substrate 102 via solder balls 112 positioned on the surface 108 along the edges of the cavity 106. The semiconductor device 100 may be mounted to the bridge 110 via a bumping technique using gold bumps 114. The bridge 110 may include conductive leads that communicatively couple with features of the substrate via the solder balls 112 and with the semiconductor device 100 via the gold bumps 114. In other embodiments, different techniques, such as thermo compression bonding and isotropic paste may be utilized to communicatively couple the semiconductor device 100 to the bridge 110. Likewise, other techniques may be utilized to couple the bridge 110 to the substrate 102. Additionally, in some embodiments, the semiconductor device 100 may simply be held in place by the bridge 110 and may communicate with other components via a radio frequency (RF) feature.

As indicated above, in the illustrated embodiment, the semiconductor device 100 is coupled to the bridge 110. Specifically, the semiconductor device 100 is extending from the bridge 110 into the cavity 106 by the gold bumps 114 such that it does not touch the sides of the cavity 106. However, in some embodiments, the semiconductor device 100 may contact a side or bottom portion of the cavity 106. Indeed, such contact may provide additional support to facilitate holding the semiconductor device 100 in a particular position, or facilitate cooling of the semiconductor device 100 (e.g., a microprocessor) by increasing heat transfer between the semiconductor device 100 and the substrate 102. Additionally, in some embodiments, the semiconductor device 100 may be disposed within the cavity 106 and coupled to a wall of the cavity 106, thus further facilitating stabilization and/or heat transfer.

In addition to conserving space and facilitating miniaturization of electronic devices, present embodiments may also provide operational benefits. For example, present embodiments may be utilized to provide a microphone or sound component for a cell phone, a hearing aid, television, medical device, or the like. In such embodiments, it may be beneficial for certain components to be positioned close to an outside portion of the device. For example, the semiconductor device 100 may include microphone circuitry that would benefit from being disposed within the substrate 102 forming the outer wall of the hearing aid, cell phone or the like. This close proximity to the outer wall of the device's enclosure may facilitate sound detection. Further, in some embodiments, as illustrated by FIG. 2, a hole 116 that extends all the way through the substrate 102 may be located at the base of the cavity 106. The hole 116 may further facilitate transmission of sound and so forth from outside of the substrate 102 (e.g., cell phone housing) to the semiconductor device 100 (e.g., microphone).

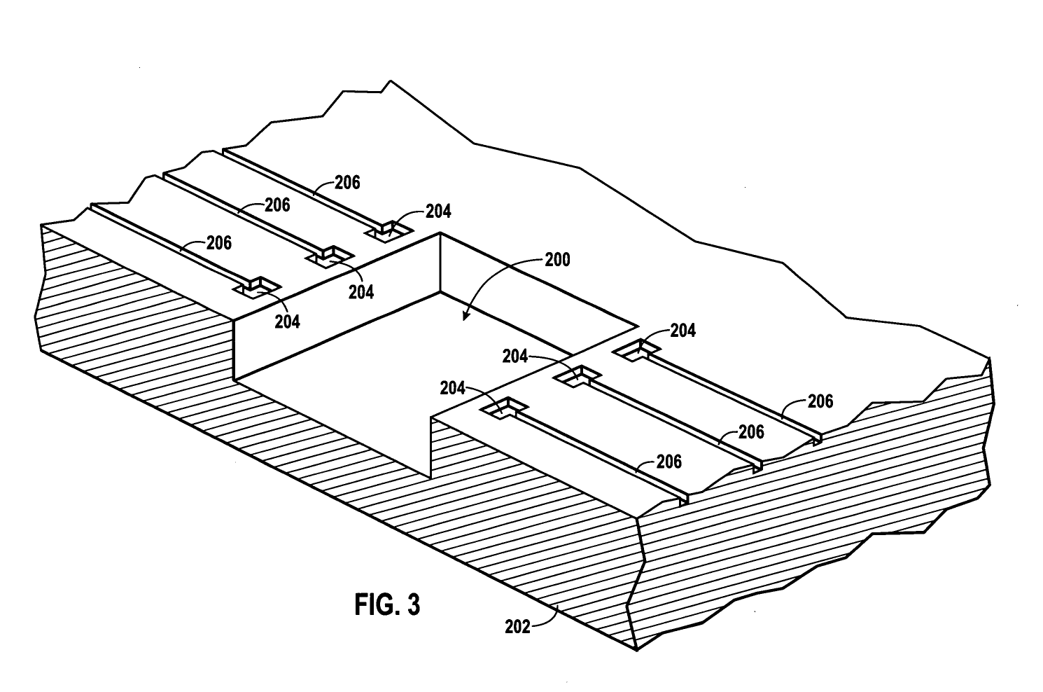

FIG. 3 depicts a perspective view of a cavity 200 formed in a substrate 202 of an electronic device and configured to receive a TAB mounted die in accordance with present embodiments. The cavity 200 may be formed via a hot embossing tool, a laser, or the like. Similarly, various trenches, vias, and the like may be formed within and around the cavity 200 using the same hot embossing tool, laser, or the like. For example, in the illustrated embodiment, pad trenches 204 and trace trenches 206 are formed around the cavity 200. These trenches 204, 206 may eventually facilitate communicative coupling of a die within the cavity 200 when filled with conductive material. It should be noted that by utilizing the same technique for creating the trenches 204, 206 and the cavity 200, present embodiments may facilitate avoidance or reduced use of thermal compression techniques.

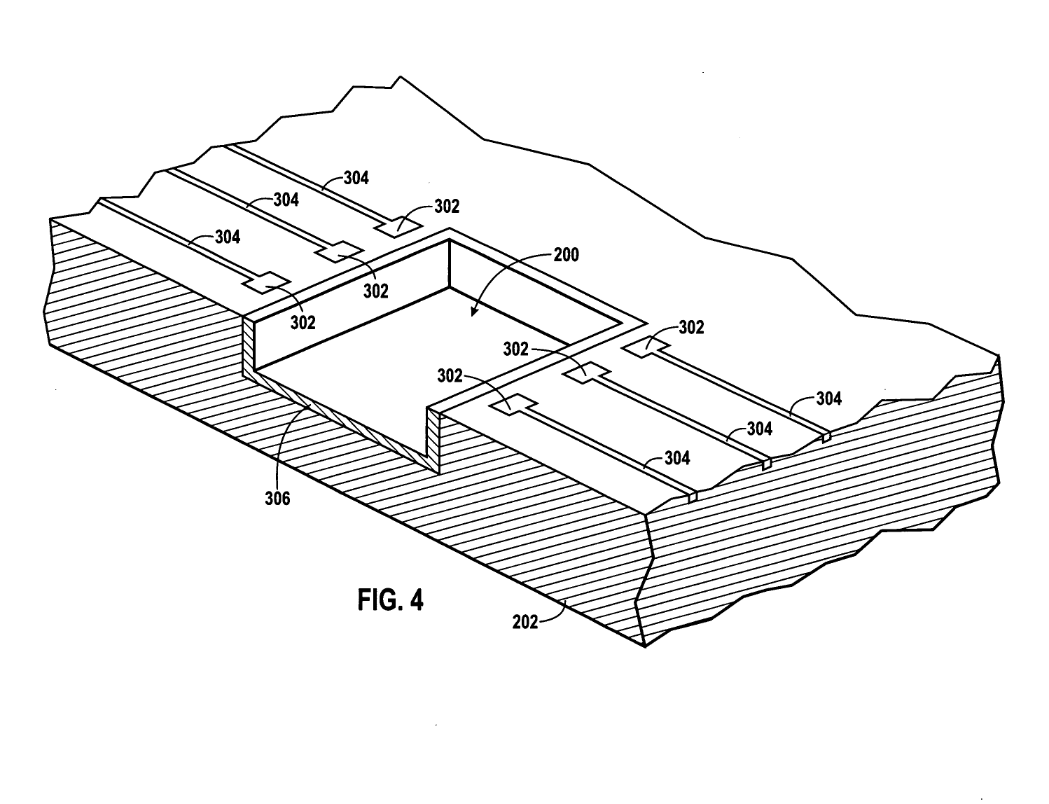

The contact pad trenches 204 and trace trenches 206 may be electroplated with copper, gold, nickel, or the like, to form bond pads 302 and conductive traces 304, respectively, as illustrated in FIG. 4. These features may be utilized to facilitate electronic communication between other components of the electronic device and/or other features of the substrate 202. The cavity 100 may also be electroplated in accordance with present embodiments. For example, in FIG. 4, the sides of the cavity 200 are electroplated with a metallic layer 306. This electroplating of the cavity 200 may provide electromagnetic shielding to a die disposed within the cavity 200, as will be discussed in further detail below.

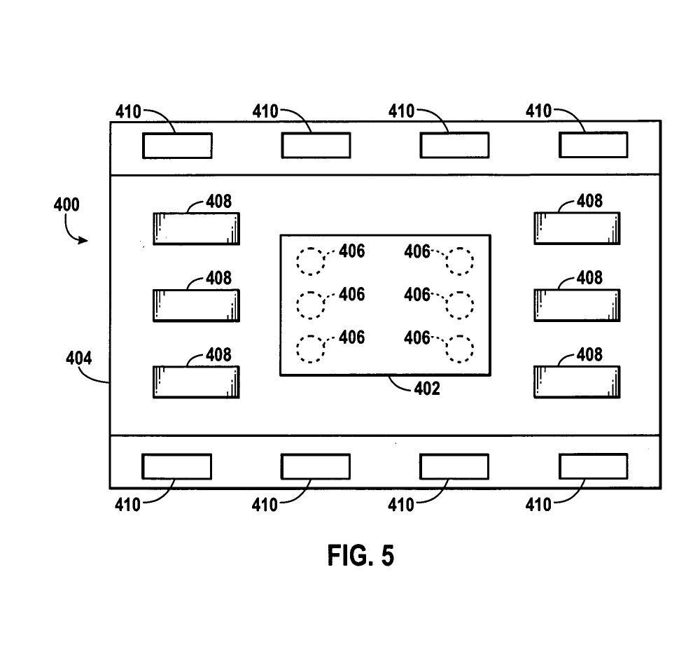

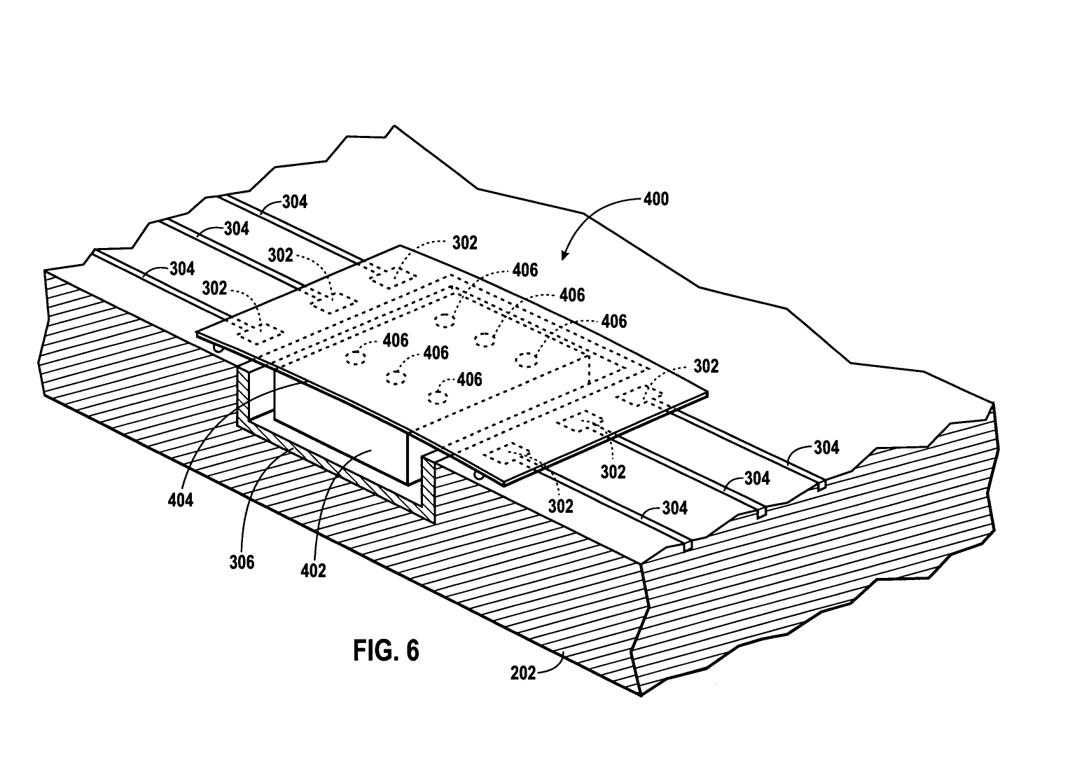

FIG. 5 depicts a TAB mounted die feature 400 configured for coupling with the substrate 202 in accordance with present embodiments. The TAB mounted die feature 400 includes an integrated circuit 402 that is mounted to a piece of TAB tape 404 with bumps 406. The TAB tape 404 includes leads 408 that are configured to communicatively couple with the bond pads 302 on the substrate 202. For example, the TAB tape 404 may be thermode bonded to the bond pads 302 via the leads 408. Additionally, the TAB tape 404 includes slots 410 that may facilitate manipulation of the TAB tape 404 with appropriate equipment. When the TAB mounted die feature 400 is coupled with the substrate 202, the TAB tape 404 spans the cavity 200 and couples to the bond pads 302 on opposite sides of the cavity 200, while the integrated circuit 402 is held within the cavity 200. For example, FIG. 6 is a perspective view of the TAB mounted die feature 400 coupled with the substrate 202 such that the integrated circuit 402 is suspended within the cavity 200. As illustrated in FIG. 6, the TAB mounted die feature 400 may couple with the substrate 202 via a coupling between the leads 408 and the bond pads 302. Further, the TAB tape 404 may couple with the integrated circuit 402 via the bumps 406.

The TAB tape 404 or another bridge may be configured to cooperate with the cavity to provide electromagnetic shielding in accordance with present embodiments. As discussed above, the cavity 200 may be electroplated such that the integrated circuit 402 is essentially surrounded by the metallic layer 306, which provides electromagnetic shielding. The metallic layer 306 may include metals such as electrodeposited copper, gold, or tin with a nickel underlayer. However, the side of the integrated circuit 402 that is directly coupled to the TAB tape 404 may not be protected by the lining 306 of the cavity 200. Accordingly, in present embodiments, bridging material, such as the material forming the TAB tape 404, may include a shielding layer. For example, the TAB tape 404 may include a solid metal layer or conductive traces arranged in a pattern or a mesh that is sufficient to provide electromagnetic shielding. Indeed, when the bridge material is disposed over the cavity 200, the cavity 200 and the bridge (e.g., the TAB tape 404) may cooperate to constitute a Faraday cage in accordance with present embodiments.

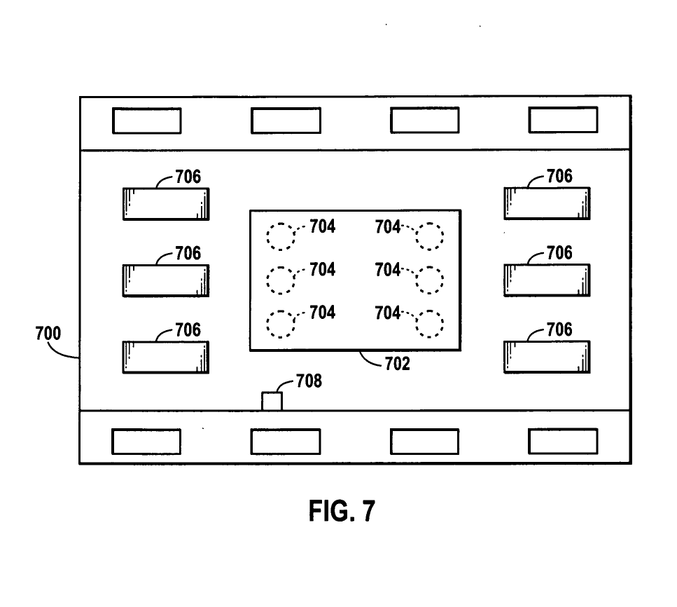

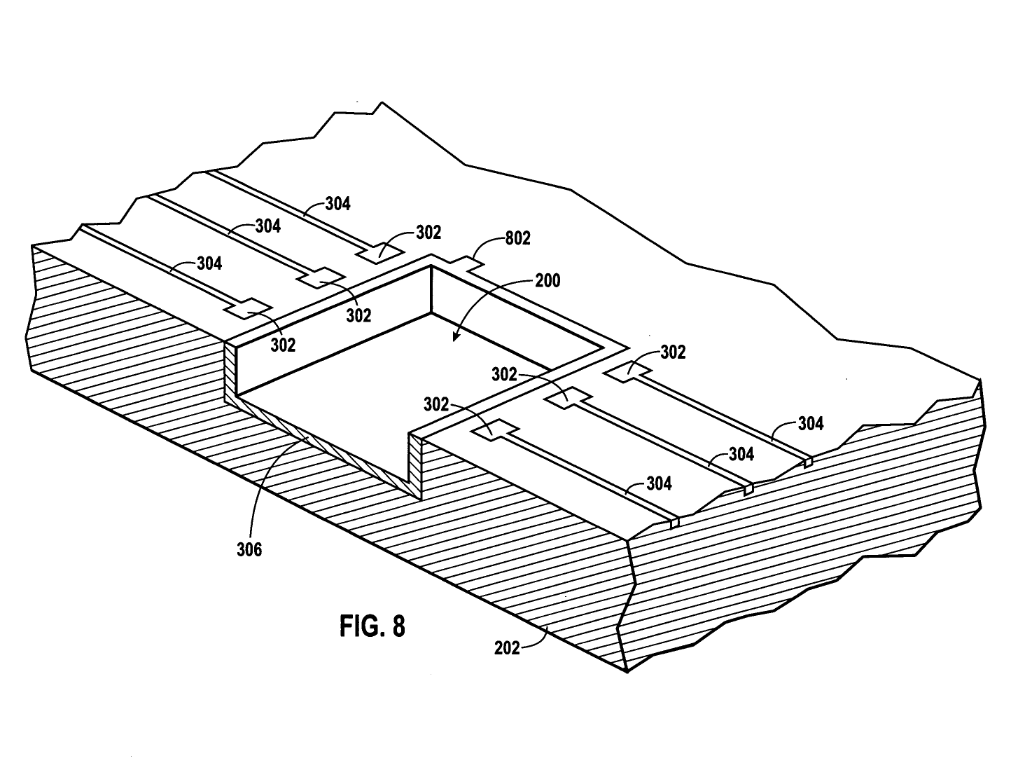

In some embodiments, as illustrated in FIG. 7, in addition to a die 702 coupled to the bridge 700 via solder balls 704, and conductive leads 706 disposed on edges of the bridge 700 for coupling with the substrate 202, a bridge 700 may include one or more instances of a circuit pad 708 that is configured to couple with the lining 306 of the cavity 200. Specifically, the circuit pad 708 may be positioned on a bottom layer of the bridge 700 and connected to a layer of conductive traces in the bridge 700 with a via. Correspondingly, as illustrated in FIG. 8, the substrate 202 may include, along the edge of the cavity 200, one or more instances of a substrate pad 802 configured for coupling the lining 306 of the cavity 200 with one or more circuit pads, such as the circuit pad 708 of the bridge 700. The coupling of the circuit pad 708 with the substrate pad 802 may facilitate cooperation between the bridge 700 and the cavity 200 in providing shielding for the die 702.

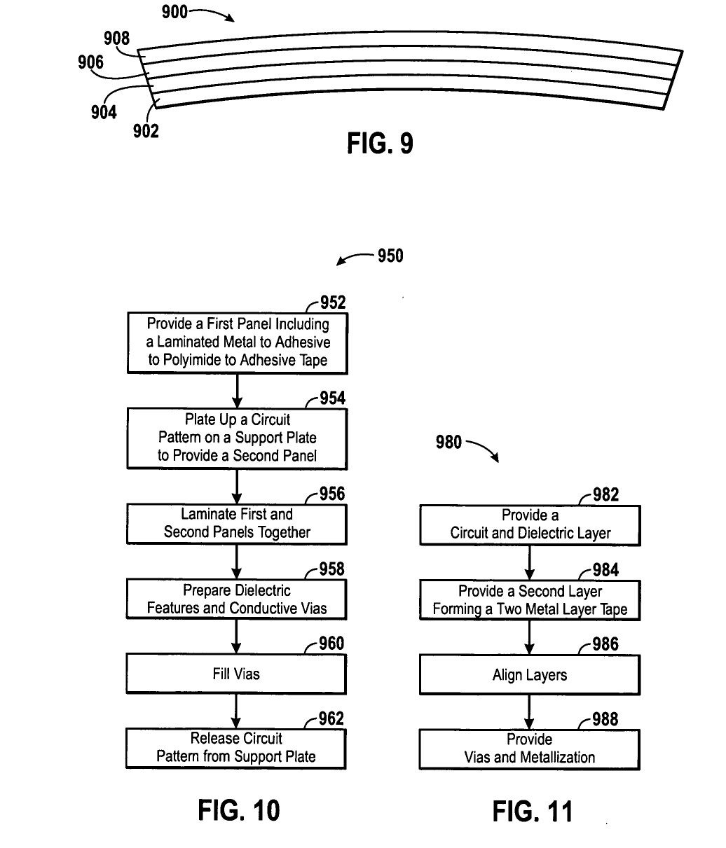

FIG. 9 depicts a cross-sectional view of exemplary bridge material 900 (e.g., tape) in accordance with present embodiments. The bridge material 900 may be supplied in rolls (e.g., a roll of tape) that can be sectioned to provide bridges, such as the TAB mounted die feature 400 discussed above. In the illustrated embodiment, the bridge material 900 includes four layers. Specifically, the bridge material 900 includes a laminated metallic layer 902 (e.g., a laminated copper layer), an adhesive layer 904 (e.g., acrylic), a polymer layer 906 (e.g., a polyimide layer), and a shielding layer 908 (e.g., conductive mesh). In the illustrated embodiment, the laminated metallic layer 902 is attached to the polymer layer 906 by the adhesive layer 904, and the shielding layer 908 is electroplated onto a side of the polymer layer 906 opposite the adhesive layer 904. The laminated metallic layer 902 may be nominally 1.4 mils (within a usual range of +0.6/−0.4 mils) thick, the adhesive layer 904 may be nominally 1.0 mils (within a usual range of +0.10/−0.5 mils) thick, the shielding layer 908 may be approximately 1.4 mils (within a usual range of +0.6/−0.4 mils) thick, and the polymer layer 906 may be nominally 4 mils (within a usual range of ±1.0 mils) thick. The traces of the mesh layer 908 may be arranged with respect to one another such that the mesh layer 908 is essentially closed to certain wavelengths.

While the bridge material 900 illustrated in FIG. 9 includes four layers, in other embodiments, more or fewer layers may be employed. For example, in some embodiments, the bridge material 900 may only include two or three layers. In another embodiment wherein the bridge 900 only includes two layers, the two layers may include the mesh layer 908 electroplated onto the polymer layer 906 without any additional substantive layers. In another embodiment, the bridge material 900 may comprise a fifth layer including circuitry.

A process for construction of the bridge material 900 may use a hybrid combination of two-layer and modified three-layer TAB technology, as illustrated in FIG. 10. Specifically, FIG. 10 is a process flow diagram representing a method 950 in accordance with present embodiments. The method 950 may begin with providing a first panel including three layers, as illustrated by block 952. For example, the first panel may include a tape having a laminated metal layer (e.g., laminated copper) coupled to a polymer layer via an adhesive layer. Another layer may then be produced using an additive process, as illustrated by block 954, to plate up a circuit pattern on what may be referred to as a support plate, thus providing a second panel. The first and second panels may then be laminated together in a press, as indicated by block 956. Dielectric features and conductive vias may be made in the bridge material 900 using laser etching, as illustrated by block 958. The vias may be filled using an additive plating process, as illustrated by block 960. Then the support plate may be caused to release the circuit pattern, as illustrated by block 962. Thus, the tape including the laminated metal layer coupled to the polymer layer via the adhesive layer may be adhered to the circuit pattern. It should be note that this may be referred to as a Type II Hybrid TAB construction method.

In another combination, as illustrated by FIG. 11, the construction of the bridge material 900 and related features (e.g., feature 400), may be achieved with the established Type I Multilayer Adhesive Construction method 980. The fabrication of a two metal layer structure may be initiated by using a standard three-layer tape to provide a circuit and a dielectric layer, as illustrated by block 982. Addition of a second metal to adhesive layer, as a continuous panel, to the standard three-layer tape may provide a second metal layer forming a two metal layer tape, one constituting the circuit, and the other, which after etching, will result in shielding mesh, as illustrated in block 984. Tooling pins may be used to align the layers during the lamination in a vacuum press, as illustrated in block 986. A via from the shielding mesh layer to circuit layer pad may be drilled using a laser, and metallization may be done via an electroless copper process, as illustrated by block 988.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents, and alternatives falling within the spirit and scope of the invention as defined by the following appended claims.

What is claimed is:

1. An electronic device, comprising:
a substrate;
a cavity formed in the substrate;
a bridge coupled to the substrate and spanning the cavity; and
a semiconductor device coupled to the bridge such that the semiconductor device is positioned within the cavity.

2. The electronic device of claim 1, wherein the substrate comprises a device enclosure.

3. The electronic device of claim 1, wherein the substrate comprises a printed circuit board.

4. The electronic device of claim 1, wherein the bridge comprises a tape automated bonding tape.

5. The electronic device of claim 1, wherein the semiconductor device comprises a microprocessor.

6. The electronic device of claim 1, wherein the bridge comprises a layer of electromagnetic shielding material.

7. The electronic device of claim 1, wherein the cavity is coated with a layer of metal.

8. The electronic device of claim 1, wherein a base of the cavity comprises a hole that passes through the substrate from one side of the substrate to an opposite side of the substrate.

9. The electronic device of claim 1, wherein the cavity and the bridge cooperate to constitute a Faraday cage.

10. The electronic device of claim 1, wherein the electronic device comprises a hearing aid, a blue tooth headset, a watch, an implantable medical device, or a television.

11. A method of providing a miniaturized electronic device, comprising:
positioning a bridge with a die attached thereto over a cavity in a substrate such that the die is positioned within the cavity; and
coupling the bridge to the substrate such that it spans the cavity.

12. The method of claim 11, comprising hot-embossing or laser-etching the cavity into the substrate.

13. The method of claim 11, wherein positioning the bridge comprises aligning a piece of tape automated bonding tape with the cavity.

14. The method of claim 11, comprising attaching the die to the bridge with a bumping technique.

15. The method of claim 11, comprising electroplating the cavity prior to positioning the die within the cavity.

16. The method of claim 11, comprising disposing an electromagnetic shielding layer on a polymer layer to form the bridge.

17. Automated bonding tape, comprising:
a first layer comprising a laminated metal;
a second layer comprising a polymer;
a third layer comprising an adhesive that couples the first layer to the second layer; and
a fourth layer comprising material configured to provide electromagnetic shielding.

18. The tape automated bonding tape of claim 17, wherein the laminated metal comprises laminated copper.

19. The tape automated bonding tape of claim 17, comprising a fifth layer comprising a circuit.

20. The tape automated bonding tape of claim 19, wherein the fifth layer comprises a circuit pad configured to couple with a substrate pad, wherein the circuit pad is communicatively connected to the fourth layer by a via.

21. The tape automated bonding tape of claim 17, wherein the fourth layer comprises conductive traces arranged in a mesh pattern configured to provide electromagnetic shielding.

22. A support feature, comprising:
a bridge comprising:
a first layer comprising a polymer; and
a second layer comprising material configured to provide electromagnetic shielding; and
a semiconductor device coupled to the bridge, wherein the bridge is configured to span a cavity formed in a substrate and hold the semiconductor device within the cavity.

23. The support feature of claim 22, wherein the second layer comprises conductive traces arranged in a mesh pattern configured to provide electromagnetic shielding.

24. The support feature of claim 22, wherein the tape automated bonding mounted die feature is coupled with a plurality of other tape automated bonding mounted die features in a roll.

25. A bridge configured to span a cavity in a substrate and hold a die within the cavity, the bridge comprising:
a first layer comprising laminated copper;
a second layer comprising polyimide; and
a third layer comprising traces arranged in a mesh and configured to provide electromagnetic shielding.
